(19) United States
(12) Patent Application Publication
(10) Pub. No.: US 2020/0006167 A1
(43) Pub. Date: Jan. 2, 2020

(54) SEALING SHEET AND METHOD FOR PRODUCING SEMICONDUCTOR DEVICE

(71) Applicant: LINTEC CORPORATION, Tokyo (JP)

(72) Inventors: Yusuke NEZU, Tokyo (JP); Takashi SUGINO, Tokyo (JP)

(21) Appl. No.: 16/488,531

(22) PCT Filed: Feb. 5, 2018
(86) PCT No.: PCT/JP2018/003726

§ 371 Date: Aug. 23, 2019

(30) Foreign Application Priority Data
Mar. 3, 2017 (JP) 2017-040576

(51) Int. Cl. H01L 23/14; H01L 23/29; H01L 23/31; C08K 3/36; H01L 33/56

(52) U.S. Cl. CPC H01L 23/142; H01L 23/291; H01L 33/56; C08K 3/36; H01L 23/3171

(57) ABSTRACT

A sealing sheet is provided which is used for sealing of a semiconductor chip embedded in a substrate or a semiconductor chip on a pressure sensitive adhesive sheet in a method for producing a semiconductor device. The method includes a treatment step using an alkaline solution. The sealing sheet includes at least an adhesive layer having curability. The adhesive layer is formed of an adhesive composition that contains a thermoset resin, a thermoplastic resin, and an inorganic filler. The inorganic filler is surface-treated with a surface treatment agent having a minimum coverage area of 550 m²/g or more and 1,500 m²/g or less. The sealing sheet is less likely to cause the inorganic filler to escape from a cured layer 11′.

### TECHNICAL FIELD

The present invention relates to a sealing sheet and a method for producing a semiconductor device using the sealing sheet.

### BACKGROUND ART

In a conventional method for producing a semiconductor device, semiconductor chips may be sealed using a sealing sheet that includes a layer (adhesive layer) in which a sealing material is formed in a sheet-like shape. For example, the adhesive layer of the sealing sheet is laminated on the semiconductor chips provided on a substrate, and the adhesive layer is then cured to seal the semiconductor chips (Patent Document 1).

In recent years, substrates in which semiconductor chips are embedded (such a substrate may be referred to as a “chip-embedded substrate,” hereinafter) are being developed. Also in the production of such a substrate, the semiconductor chips may be sealed. In this case, after the semiconductor chips are provided on a base material and the adhesive layer of a sealing sheet is laminated on a surface of the base material on which the semiconductor chips are provided, the adhesive layer may be cured. Subsequent steps for obtaining a chip-embedded substrate may include forming holes to penetrate the cured layer, which is formed by curing the adhesive layer, and forming electrodes to electrically connect the semiconductor chips to the external via the holes.

### PRIOR ART DOCUMENTS

### Patent Documents

[Patent Document 1] JP2006-19714A

### SUMMARY OF THE INVENTION

### Problems to be Solved by the Invention

Currently, a method of sealing semiconductor chips on a pressure sensitive adhesive sheet is also being developed. This method includes laminating the adhesive layer of a sealing sheet on semiconductor chips provided on the pressure sensitive adhesive sheet and curing the adhesive layer to obtain a sealed body in which the semiconductor chips are sealed. The sealed body may be further provided with electrodes. In this case, the pressure sensitive adhesive sheet is removed from the sealed body, and an interlayer insulating film is laminated on the exposed surface of the sealed body. Thereafter, holes are formed to penetrate the interlayer insulating film, and electrodes are formed to electrically connect the semiconductor chips to the external via the holes. Such a method allows for production of a fan-out wafer level package (FOWLP) and the like.

In the method for producing the above-described chip-embedded substrate, FOWLP, or the like, resin residues (which may be referred to as “smear,” hereinafter) may be generated when forming the holes in the cured layer or in the interlayer insulating film, and the smear may remain in the holes. If the electrodes are formed in a state in which the smear remains in the holes, problems such as conduction failure of the electrodes will readily occur. To avoid such problems, the formation of holes may therefore be followed by desmear treatment for removing the generated smear. Such desmear treatment may also be performed when holes for alignment are formed.

The desmear treatment may be performed by a method of exposing the object to be treated to an alkaline solution. According to this method, the smear can be dissolved in the alkaline solution and removed. In another situation, the treatment using an alkaline solution may be performed for the purpose of forming fine irregularities on the resin surface of a product. In this case, the resin surface is partially dissolved by the alkaline solution to form irregularities on the surface.

When the treatment with an alkaline solution as described above is performed for a sealed body formed using the conventional sealing sheet, however, another problem may occur in that a large number of inorganic filler particles existing in the cured layer escape from the cured layer. The cured layer in which such escape of the inorganic filler has occurred may readily expand when heated. Such expansion of the cured layer may occur as the temperature of the cured layer increases during the subsequent production steps for semiconductor devices or during the use of semiconductor devices; therefore, from the viewpoint of producing semiconductor devices having good performance, it is required that such expansion as the above does not occur.

The present invention has been made in consideration of such actual circumstances and an object of the present invention is to provide a sealing sheet in which the inorganic filler does not escape from the cured layer. The present invention also provides a method for producing a semiconductor device having good performance using such a sealing sheet.

### Means for Solving the Problems

To achieve the above object, first, the present invention provides a sealing sheet used for sealing of a semiconductor chip embedded in a substrate or a semiconductor chip on a pressure sensitive adhesive sheet in a method for producing a semiconductor device, the method comprising a treatment step using an alkaline solution, the sealing sheet comprising at least an adhesive layer having curability, the adhesive layer being formed of an adhesive composition, the adhesive composition containing a thermoset resin, a thermoplastic resin, and an inorganic filler, the inorganic filler being surface-treated with a surface treatment agent having a minimum coverage area of 550 m²/g or more and 1,500 m²/g or less (Invention 1).

In the sealing sheet according to the above invention (Invention 1), a large part of hydroxy groups existing on the surfaces of the inorganic filler disappears due to the reaction with the surface treatment agent having the minimum coverage area within the above range. When the cured layer is exposed to an alkaline solution, therefore, the inorganic filler is less likely to escape from the cured layer. As a result, expansion of the cured layer due to heating is suppressed.

In the above invention (Invention 1), the surface treatment agent may preferably be at least one selected from the group consisting of a silazane compound, an alkoxysilane, and a silane coupling agent (Invention 2).

In the above invention (Invention 2), the silazane compound may preferably be a compound having a structure represented by the following Formula (1):

SiR₃—N(H)—SiR₃ (1)

where each R independently represents a substituted or unsubstituted alkyl group having a carbon number of 1 or more and 6 or less (Invention 3).

In the above invention (Invention 1 to 3), the inorganic filler may preferably be a silica filler or an alumina filler (Invention 4).

In the above invention (Invention 1 to 4), the average particle diameter of the inorganic filler may preferably be 0.01 μm or more and 3.0 μm or less (Invention 5).

In the above invention (Invention 1 to 5), the maximum particle diameter of the inorganic filler may preferably be 0.05 μm or more and 5.0 μm or less (Invention 6).

In the above invention (Invention 1 to 6), the inorganic filler may preferably be spherical (Invention 7).

In the above invention (Invention 1 to 7), the adhesive composition may further contain an imidazole-based curing catalyst (Invention 8).

Second, the present invention provides a method for producing a semiconductor device, comprising: a step of providing one or more semiconductor chips on at least one surface of a base material; a step of laminating the adhesive layer of the sealing sheet (Invention 1 to 8) so as to cover at least the semiconductor chips; a step of curing the adhesive layer to obtain a sealed body comprising: a cured layer formed by curing the adhesive layer; the semiconductor chips sealed with the cured layer; and the base material; a step of forming one or more holes penetrating from a surface of the cured layer opposite to the base material to an interface between the cured layer and the semiconductor chips; a step of exposing the sealed body formed with the holes to an alkaline solution to perform desmear treatment for the holes; and a step of forming one or more electrodes connected electrically to the semiconductor chips via the holes to obtain a chip-embedded substrate (Invention 9).

Third, the present invention provides a method for producing a semiconductor device, comprising: a step of providing one or more semiconductor chips on a pressure sensitive adhesive surface of a pressure sensitive adhesive sheet; a step of laminating the adhesive layer of the sealing sheet (Invention 1 to 8) so as to cover at least the semiconductor chips; a step of curing the adhesive layer to obtain a sealed body comprising: a cured layer formed by curing the adhesive layer; and the semiconductor chips sealed with the cured layer; a step of removing the pressure sensitive adhesive sheet from the sealed body; a step of laminating an interlayer insulating film on a surface of the sealed body exposed by removal of the pressure sensitive adhesive sheet; a step of forming one or more holes penetrating from a surface of the interlayer insulating film opposite to the sealed body to an interface between the interlayer insulating film and the semiconductor chips; a step of exposing the sealed body laminated with the interlayer insulating film formed with the holes to an alkaline solution to perform desmear treatment for the holes; and a step of forming one or more electrodes connected electrically to the semiconductor chips via the holes (Invention 10).

Fourth, the present invention provides a method for producing a semiconductor device, comprising: a step of providing one or more semiconductor chips on at least one surface of a base material or on a pressure sensitive adhesive surface of a pressure sensitive adhesive sheet; a step of laminating the adhesive layer of the sealing sheet (Invention 1 to 8) so as to cover at least the semiconductor chips; a step of curing the adhesive layer to obtain a sealed body comprising: a cured layer formed by curing the adhesive layer; and the semiconductor chips sealed with the cured layer; and a step of exposing the sealed body to an alkaline solution to form irregularities on a surface of the sealed body (Invention 11).

### ADVANTAGEOUS EFFECT OF THE INVENTION

In the sealing sheet of the present invention, the inorganic filler is less likely to escape from the cured layer. Moreover, according to the production method of the present invention, a semiconductor device having good performance can be produced using such a sealing sheet.

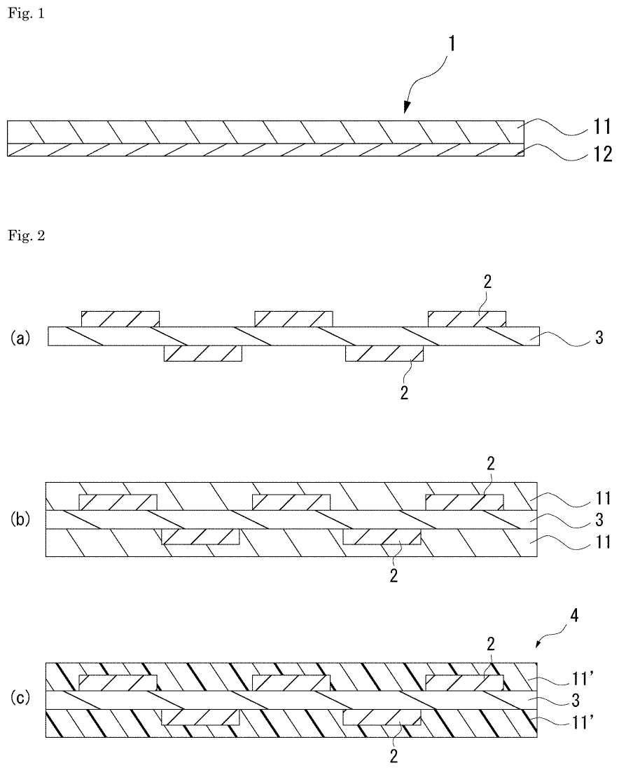

FIG. 1 is a cross-sectional view of a sealing sheet according to an embodiment of the present invention.

FIG. 2 is a set of cross-sectional views for describing a method for producing a semiconductor device according to a first embodiment.

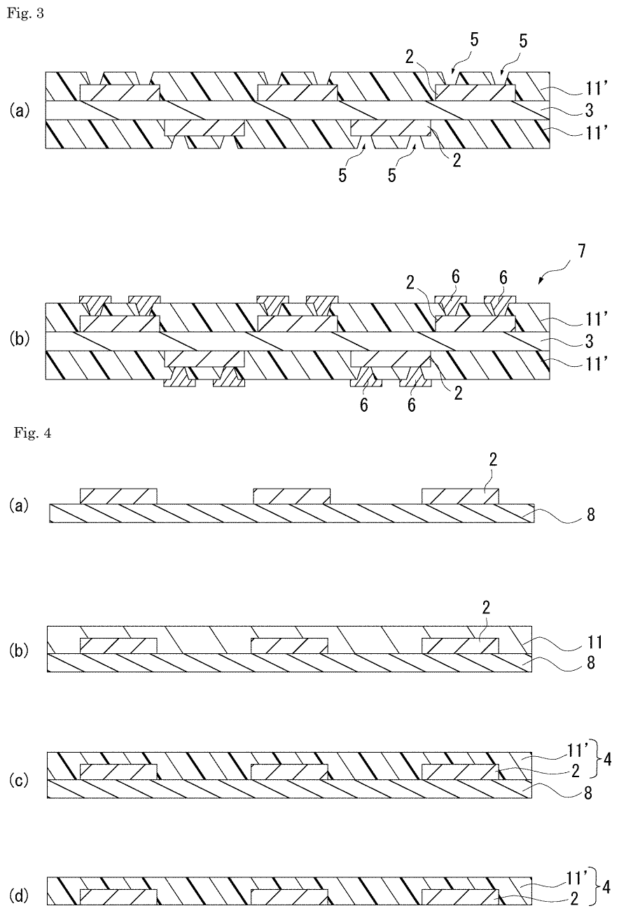

FIG. 3 is a set of cross-sectional views for describing the method for producing a semiconductor device according to the first embodiment.

FIG. 4 is a set of cross-sectional views for describing a method for producing a semiconductor device according to a second embodiment.

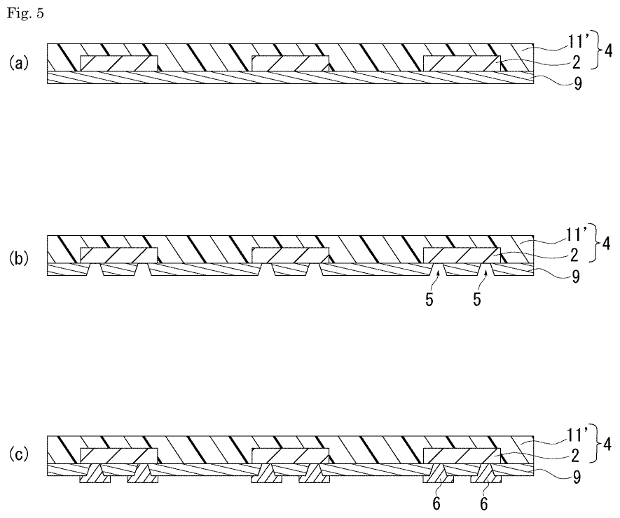

FIG. 5 is a set of cross-sectional views for describing the method for producing a semiconductor device according to the second embodiment.

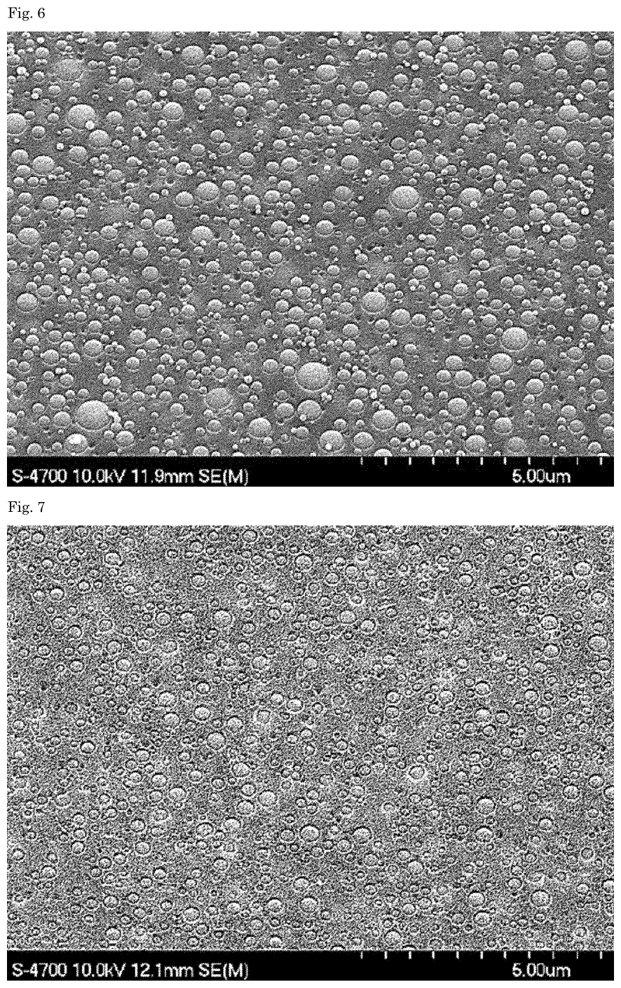

FIG. 6 is a scanning electron microscope photograph of the surface of a cured layer according to Example 1.

FIG. 7 is a scanning electron microscope photograph of the surface of a cured layer according to Example 2.

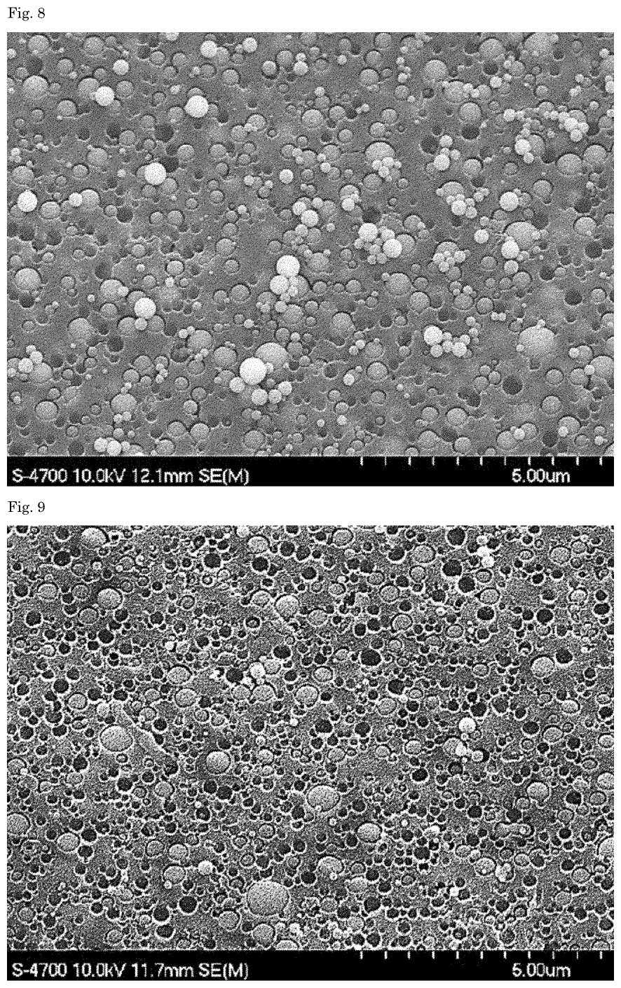

FIG. 8 is a scanning electron microscope photograph of the surface of a cured layer according to Comparative Example 1.

FIG. 9 is a scanning electron microscope photograph of the surface of a cured layer according to Comparative Example 2.

### EMBODIMENTS FOR CARRYING OUT THE INVENTION

Hereinafter, one or more embodiments of the present invention will be described.

### <Sealing Sheet>

FIG. 1 illustrates the cross-sectional view of a sealing sheet 1 according to the present embodiment. As illustrated in FIG. 1, the sealing sheet 1 according to the present embodiment comprises an adhesive layer 11 and a release sheet 12 laminated on at least one surface of the adhesive layer 11. Another release sheet may further be laminated on the surface of the adhesive layer 11 opposite to the release sheet 12. Note, however, that the release sheet 12 and the other release sheet may be omitted.

The sealing sheet 1 according to the present embodiment is used for sealing of semiconductor chips in a method for producing a semiconductor device. The method includes a treatment step using an alkaline solution. The sealing may be sealing of semiconductor chips embedded in a substrate or sealing of semiconductor chips on a pressure sensitive adhesive sheet. The semiconductor device produced using the sealing sheet 1 according to the present embodiment includes sealed semiconductor chips. Examples of such a semiconductor device include semiconductor packages such as a fan-out wafer level package (FOWLP) and a fan-in wafer level package (FIWLP)

In the sealing sheet 1 according to the present embodiment, the adhesive layer 11 has curability. Here, having curability means that the adhesive layer 11 can be cured by heating or the like. That is, the adhesive layer 11 is uncured in a state in which the adhesive layer 11 constitutes the sealing sheet 1. The adhesive layer 11 may preferably be thermoset. This allows the adhesive layer 11 to be well cured even when it is difficult for the laminated adhesive layer 11 to be irradiated with energy rays.

In the sealing sheet 1 according to the present embodiment, the adhesive layer 11 is formed of an adhesive composition that contains a thermoset resin, a thermoplastic resin, and an inorganic filler. The inorganic filler is surface-treated with a surface treatment agent.

The above surface treatment agent has a minimum coverage area of 550 m²/g or more and 1,500 m²/g or less.

As described above, the adhesive layer 11 is formed of the adhesive composition containing the inorganic filler which is surface-treated with the above surface treatment agent and, therefore, the cured layer formed by curing the adhesive layer 11 also contains the inorganic filler. Here, even in the inorganic filler having a large number of hydroxy groups on the surfaces in the untreated state, when the surface treatment is performed as described above, a large part of the hydroxy groups existing on the surfaces of the inorganic filler disappears due to the reaction with the reactive groups of the surface treatment agent.

In particular, in the surface treatment agent having the minimum coverage area within the above range, the molecular weight of other portions than the reactive groups in the molecule is smaller, that is, the physical size of those portions is smaller, as compared with other surface treatment agents. When such a surface treatment agent reacts with the hydroxyl groups on the surfaces of the inorganic filler, collision between those portions of the surface treatment agent is less likely to occur. It is thus expected that the reaction between the surface treatment agent and the hydroxy groups progresses well without interruption, so that a large part of the hydroxy groups existing on the surfaces of the inorganic filler disappears.

The inorganic filler in which a large part of the hydroxy groups existing on the surfaces has disappeared in this manner has a relatively low affinity to an alkaline solution. When the cured layer is exposed to an alkaline solution, therefore, the inorganic filler may not readily escape from the cured layer. Here, if the inorganic filler escapes, the resulting voids will be occupied by air, and when the cured layer is heated, the air expands and the entire cured layer also expands accordingly. Fortunately, however, in the cured layer formed using the sealing sheet 1 according to the present embodiment, voids caused due to escape of the inorganic filler and therefore expansion of air are less likely to occur, and expansion of the cured layer due to heating can be suppressed.

### 1. Adhesive Layer

(1) Inorganic Filler

In the sealing sheet 1 according to the present embodiment, the inorganic filler contained in the adhesive composition is surface-treated with the surface treatment agent. This can suppress the escape of the inorganic filler from the cured layer. Moreover, the adhesive composition containing the inorganic filler allows the cured layer to have excellent mechanical strength, and the reliability of the obtained semiconductor device can be improved.

In the sealing sheet 1 according to the present embodiment, effects by the surface treatment agent are exhibited for the inorganic filler which has hydroxyl groups on the surfaces. Examples of such an inorganic filler include fillers of inorganic materials such as silica, alumina, glass, titanium oxide, aluminum hydroxide, magnesium hydroxide, calcium carbonate, magnesium carbonate, calcium silicate, magnesium silicate, calcium oxide, magnesium oxide, aluminum oxide, aluminum nitride, aluminum borate whisker, boron nitride, crystalline silica, amorphous silica, composite oxides such as mullite and cordierite, montmorillonite, and smectite. These can each be used alone or two or more types can also be used in combination. Among these, silica filler or alumina filler may be preferably used and silica filler may be particularly preferably used.

The shape of the inorganic filler may be any of granular, needle-like, plate-like, indeterminate, and the like, among which a spherical shape may be preferred. The spherical shape of the inorganic filler allows the surface treatment to be effectively performed with the surface treatment agent.

The average particle diameter of the above inorganic filler may be preferably 0.01 μm or more, particularly preferably 0.1 μm or more, and further preferably 0.3 μm or more. From another aspect, the average particle diameter of the above inorganic filler may be preferably 3.0 μm or less and particularly preferably 1.0 μm or less. When the average particle diameter of the inorganic filler is 0.01 μm or more, the size of the inorganic filler is sufficiently larger as compared with the molecules of the surface treatment agent, and collisions between particles of the surface treatment agent is less likely to occur on the surfaces of the inorganic filler. Thus, the surface treatment can be effectively performed. As a result, when the cured layer is exposed to an alkaline solution, escape of the inorganic filler can be well suppressed. On the other hand, when the average particle diameter of the inorganic filler is 3.0 μm or less, the inorganic filler can have a surface area that can be readily surface-treated with the surface treatment agent, and it is possible to effectively perform the surface treatment. In addition, the cured layer is well filled with the inorganic filler, and the cured layer can have more excellent mechanical strength. As used in the present description, the average particle diameter of the inorganic filler refers to a value as measured by a dynamic light scattering method using a particle diameter distribution measuring apparatus (available from NIKKISO CO., LTD., product name “Nanotrac Wave-UT 151”).

The maximum particle diameter of the above inorganic filler may be preferably 0.05 μm or more and particularly preferably 0.5 μm or more. From another aspect, the maximum particle diameter may be preferably 5 μm or less and particularly preferably 3 μm or less. When the maximum particle diameter of the inorganic filler falls within the above range, the cured layer can be readily filled with the inorganic filler, and the cured layer can have more excellent mechanical strength.

The minimum coverage area of the surface treatment agent is 550 m²/g or more and may be preferably 600 m²/g or more. From another aspect, the minimum coverage area of the surface treatment agent is 1,500 m²/g or less and may be preferably 1,200 m²/g or less and particularly preferably 1,000 m²/g or less. When the minimum coverage area falls within the above range, the molecular weight of other portions than the reactive groups in the surface treatment agent is relatively small, that is, the physical size of those portions is relatively small; therefore, it is expected that when reacting with the hydroxy groups on the surfaces of the inorganic filler, collision between those portions of the surface treatment agent is less likely to occur. Thus, by using the surface treatment agent having the above minimum coverage area, the hydroxy groups existing on the surfaces of the inorganic filler can disappear effectively and, as a result, the escape of the inorganic filler from the cured layer can be effectively suppressed.

Here, the minimum coverage area (m²/g) of the surface treatment agent refers to the area (m²) of a monomolecular film when the monomolecular film is formed using 1 g of the surface treatment agent. The minimum coverage area can be theoretically calculated from the structure or the like of the surface treatment agent. For example, when a surface treatment agent having trialkoxysilane groups as the reactive groups is considered, the structure of Si(O)₃ generated by hydrolysis of the trialkoxysilane groups is a tetrahedron with one Si atom and three O atoms as vertices. Here, it is assumed that the Si atom is a sphere with a radius of 2.10 Å, the O atom is a sphere with a radius of 1.52 Å, the distance of an Si—O bond is 1.51 Å, and the angle formed by the sides of two Si—O bonds is 109.5°. Then, on the assumption that all of the three O atoms in the tetrahedron react with the hydroxy groups on the surfaces of the inorganic filler, the minimum circular area which the three O atoms can cover is calculated as 1.33×10⁻¹⁹ m²/molecule for each one molecule of the surface treatment agent. This can be converted to 8.01×10⁴ m²/mol for one mol. By dividing this area per one mol by the molecular weight of the surface treatment agent, the minimum coverage area (m²/g) of the surface treatment agent can be obtained.

The surface treatment agent may preferably be at least one selected from the group consisting of a silazane compound, an alkoxysilane, and a silane coupling agent. In such a surface treatment agent, the molecular weight of other portions than the reactive groups in the surface treatment agent is relatively small, that is, the physical size of those portions is relatively small; therefore, it is expected that when reacting with the hydroxy groups on the surfaces of the inorganic filler, collision between those portions of the surface treatment agent is less likely to occur. Thus, by using such a surface treatment agent, the hydroxy groups existing on the surfaces of the inorganic filler can disappear more effectively and, as a result, the escape of the inorganic filler from the cured layer can be more effectively suppressed.

The above silazane compound may preferably be a compound having a structure represented by the following Formula (1):

SiR₃—N(H)—SiR₃ (1)

where each R independently represents a substituted or unsubstituted alkyl group having a carbon number of 1 or more and 6 or less.

In the above Formula (1), the carbon number of the alkyl group may be preferably 4 or less and particularly preferably 2 or less. Examples of the above alkyl group include a methyl group, an ethyl group, a propyl group, an isopropyl group, and a butyl group, among which the methyl group, ethyl group, or propyl group may be preferred and the methyl group or ethyl group may be particularly preferred. When the alkyl group is substituted, part or all of the hydrogen atoms of the alkyl group may be preferably substituted by one or more fluorine atoms, one or more chlorine atoms, one or more bromine atoms, or the like and particularly preferably substituted by one or more fluorine atoms.

Specific examples of the above silazane compound include 1,1,1,3,3,3-hexamethyldisilazane, 1,3-divinyl-1,1,3,3-tetramethyldisilazane, octamethyltrisilazane, hexa(t-butyl)disilazane, hexabutyldisilazane, hexaoctyldisilazane, 1,3-diethyltetramethyldisilazane, 1,3-di-n-octyltetramethyldisilazane, 1,3-diphenyltetramethyldisilazane, 1,3-dimethyltetraphenyldisilazane, 1,3-diethyltetramethyldisilazane, 1,1,3,3-tetraphenyl-1,3-dimethyldisilazane, 1,3-dipropyltetramethyldisilazane, hexamethylcyclotrisilazane, hexaphenyldisilazane, dimethylaminotrimethylsilazane, trisilazane, cyclotrisilazane, and 1,1,3,3,5,5-hexamethylcyclotrisilazane, among which 1,1,1,3,3,3-hexamethyldisilazane may be preferably used.

Specific examples of the above alkoxysilane include methyltrimethoxysilane, methyltriethoxysilane, methyltriisopropoxysilane, methyltributoxysilane, ethyltrimethoxysilane, propyltrimethoxysilane, dimethyldimethoxysilane, phenyltrimethoxysilane, diphenyldimethoxysilane, phenylmethyldimethoxysilane, tetramethoxysilane, tetraethoxysilane, tetraisopropoxysilane, tetrabutoxysilane, 3-aminopropyltrimethoxysilane, 3-(2-aminoethyl)aminopropyltrimethoxysilane, 3-glylcidoxypropyltrimethoxysilane, 3-glycidoxypropyltriethoxysilane, γ-(meth)acryloxypropyltrimethoxysilane, (meth) acryloxybutyltrimethoxysilane, and vinyltrimethoxysilane. Among these, dimethyldimethoxysilane may be preferably used from the viewpoint that the escape of the inorganic filler can be effectively suppressed. As used in the present description, the term “(meth)acryloxy” refers to both the acryloxy and the methacryloxy. The same applies to other similar terms.

Specific examples of the above silane coupling agent include polymerizable unsaturated group-containing silicon compounds, such as vinyltrimethoxysilane, vinyltriethoxysilane and methacryloxypropyltrimethoxysilane, silicon compounds having an epoxy structure, such as 3-glycidoxypropyltrimethoxysilane and 2-(3,4-epoxycyclohexyl)ethyltrimethoxysilane, amino group-containing silicon compounds, such as 3-aminopropyltrimethoxysilane, N-(2-aminoethyl)-3-aminopropyltrimethoxysilane and N-(2-aminoethyl)-3-aminopropylmethyldimethoxysilane, 3-chloropropyltrimethoxysilane, and 3-isocyanatopropyltriethoxysilane. These may each be used alone or two or more types may also be used in combination.

The method of surface-treating the inorganic filler with the surface treatment agent is not particularly limited, and the surface treatment can be performed by a commonly-used method. For example, the surface treatment can be performed through stirring an untreated inorganic filler at an ordinary temperature using a mixing machine, spraying the surface treatment agent thereto, and then further stirring them for a predetermined time. The stirring time after the spraying may be preferably, for example, 5 minutes or more and 15 minutes or less. To sufficiently fix the surface treatment agent to the inorganic filler, after the above operation, the inorganic filler may be taken out from the mixing machine and left for a day or more, or moderate heating treatment may be performed. In addition or alternatively, to uniformly perform the surface treatment, after spraying the surface treatment agent, an organic solvent may be further added to perform the above stirring. Any known one can be used as the mixing machine. Examples of such a mixing machine include blenders such as a V blender, a ribbon blender and a bubble cone blender, mixers such as a Henschel mixer and a concrete mixer, and ball mills, among which mixers may be preferably used.

The ratio of the inorganic filler surface-treated with the surface treatment agent to the inorganic filler contained in the adhesive composition may be preferably 40 mass % or more and particularly preferably 50 mass % or more. When the ratio falls within the above range, both the effective suppression of the escape of the inorganic filler from the cured layer and the excellent mechanical strength of the cured layer can be well achieved.

The content of the inorganic filler surface-treated with the surface treatment agent in the adhesive composition may be preferably 40 mass % or more and particularly preferably 50 mass % or more. From another aspect, the content may be preferably 90 mass % or less, particularly preferably 85 mass % less, and further preferably 80 mass % or less. When the content of the inorganic filler surface-treated with the surface treatment agent falls within the above range, the adhesive layer 11 can have more excellent mechanical strength.
(2) Thermoset Resin

In the sealing sheet 1 according to the present embodiment, the adhesive composition containing the thermoset resin allows the semiconductor chips to be firmly sealed. The thermoset resin is not particularly limited, provided that it enables the curing of the adhesive layer 11. For example, a resin usually contained in a sealing material can be used. Specific examples of the thermoset resin include an epoxy resin, a phenol resin, a melamine resin, a urea resin, a polyester resin, a urethane resin, an acrylic resin, a polyimide resin, a benzoxazine resin, a phenoxy resin, an acid anhydride compound, and an amine-based compound. These can each be used alone or two or more types can also be used in combination. Among these, the epoxy resin, phenol resin, melamine resin, urea resin, acid anhydride compound, and amine-based compound may be preferably used from the viewpoint of being suitable for curing using an imidazole-based curing catalyst. In particular, from the viewpoint of exhibiting excellent adhesion properties, it may be preferred to use the epoxy resin, phenol resin, a mixture thereof, or a mixture of the epoxy resin and at least one selected from the group consisting of the phenol resin, melamine resin, urea resin, amine-based compound, and acid anhydride compound.

The epoxy resin generally has properties of being made into a three-dimensional network structure when heated and forming a rigid cured product. As such an epoxy resin, various types of known epoxy resins can be used. Specific examples of the epoxy resin include: glycidyl ethers of phenols, such as bisphenol A, bisphenol F, resorcinol, phenyl novolac and cresol novolac; glycidyl ethers of alcohols, such as butanediol, polyethylene glycol and polypropylene glycol; glycidyl ethers of carboxylic acids, such as phthalic acid, isophthalic acid and tetrahydrophthalic acid; glycidyl-type or alkyl glycidyl-type epoxy resins in which an active hydrogen bonded to a nitrogen atom is substituted by a glycidyl group, such as aniline isocyanurate; and so-called alicyclic epoxides in which epoxy is introduced, for example, by oxidizing the carbon-carbon double bound in the molecule, such as vinylcyclohexane diepoxide, 3,4-epoxycyclohexylmethyl-3,4-dicyclohexanecarboxylate and 2-(3,4-epoxy)cyclohexyl-5,5-spiro(3,4-epoxy)cyclohexan-m-dioxane. Other examples for use include an epoxy resin having a biphenyl skeleton, a triphenylmethane skeleton, a dicyclohexadiene skeleton, a naphthalene skeleton, or the like. One type of these epoxy resins can be used alone or two or more types can also be used in combination. Among the above-described epoxy resins, the glycidyl ether of bisphenol A (bisphenol A-type epoxy resin), epoxy resin having a biphenyl skeleton (biphenyl-type epoxy resin), epoxy resin having a naphthalene skeleton (naphthalene-type epoxy resin), or a combination thereof may be preferably used.

Examples of the phenol resin include bisphenol A, tetramethyl bisphenol A, diallyl bisphenol A, biphenol, bisphenol F, diallyl bisphenol F, triphenylmethane-type phenol, tetrakis phenol, novolac-type phenol, cresol novolac resin, and phenol having a biphenylaralkyl skeleton (biphenyl-type phenol). Among these, the biphenyl-type phenol may be preferably used. One type of these phenol resins can be used alone or two or more types can also be used in combination. When the epoxy resin is used as the curable resin, it may be preferred to use a phenol resin together from the viewpoint of the reactivity with the epoxy resin and the like.

The content of the thermoset resin in the adhesive composition may be preferably 10 mass % or more, particularly preferably 15 mass % or more, and further preferably 20 mass % or more. From another aspect, the content may be preferably 60 mass % or less, particularly preferably 50 mass % or less, and further preferably 40 mass % or less. When the content is 10 mass % or more, curing of the adhesive layer 11 is more sufficient, and the semiconductor chips can be sealed more firmly. When the content is 60 mass % or less, curing of the adhesive layer 11 at an unintended stage can be more suppressed, and the storage stability may be more excellent.
(3) Thermoplastic Resin

In the sealing sheet 1 according to the present embodiment, the adhesive composition containing the thermoplastic resin allows the adhesive layer 11 to be readily formed into a sheet-like shape. The thermoplastic resin is not particularly limited, provided that it allows the adhesive layer to be formed into a sheet-like shape. For example, a resin usually contained in a sealing material can be used. Examples of the thermoplastic resin include phenoxy-based resins, olefin-based resins, polyester-based resins, polyurethane-based resins, polyester urethane-based resins, acrylic-based resins, amide-based resins, styrene-based resins, silane-based resins, and rubber-based resins. These can each be used alone or two or more types can also be used in combination.

The phenoxy-based resin is not particularly limited. Examples of the phenoxy-based resin include resins of bisphenol A type, bisphenol F type, bisphenol A/bisphenol F copolymer type, bisphenol S type, bisphenol acetophenone type, novolac type, fluorene type, dicyclopentadiene type, norbornene type, naphthalene type, anthracene type, adamantane type, terpene type, trimethylcyclohexane type, biphenol type, and biphenyl type, among which the bisphenol A-type phenoxy resin may be preferably used.

The content of the thermoplastic resin in the adhesive composition may be preferably 1 mass % or more, particularly preferably 3 mass % or more, and further preferably 5 mass % or more. From another aspect, the content may be preferably 30 mass % or less, particularly preferably 20 mass % or less, and further preferably 10 mass % or less. When the content falls within the above range, the adhesive layer 11 can be more readily formed into a sheet-like shape.
(4) Imidazole-based Curing catalyst

In the sealing sheet 1 according to the present embodiment, the adhesive composition may preferably further contain an imidazole-based curing catalyst. This allows the curing reaction of the thermoset resin to effectively progress, and the adhesive layer 11 can be well cured.

Specific examples of the imidazole-based curing catalyst include 2-methylimidazole, 2-undecylimidazole, 2-heptadecylimidazole, 2-ethyl-4-methylimidazole, 1-benzyl-2-methylimidazole, 2-phenylimidazole, 2-phenyl-4-methylimidazole, 1-benzyl-2-phenylimidazole, 1,2-dimethylimidazole, 1-cyanoethyl-2-methylimidazole, 1-cyanoethyl-2-ethyl-4-methylimidazole, 1-cyanoethyl-2-undecylimidazole, 1-cyanoethyl-2-phenylimidazole, 2-phenyl-4-methyl-5-hydroxymethylimidazole, and 2-phenyl-4,5-di(hydroxymethyl)imidazole. From the viewpoint of the reactivity, it may be preferred to use 2-ethyl-4-methylimidazole. One type of the imidazole-based curing catalyst may be used alone or two or more types may also be used in combination.

The content of the imidazole-based curing catalyst in the adhesive composition may be preferably 0.01 mass % or more, particularly preferably 0.05 mass % or more, and further preferably 0.1 mass % or more. From another aspect, the content may be preferably 2.0 mass % or less, particularly preferably 1.5 mass % or less, and further preferably 1.0 mass % or less. When the content falls within the above range, the adhesive layer 11 can be better cured.
(5) Other Components

The adhesive composition may further contain another inorganic filler in addition to the inorganic filler surface-treated with the previously described surface treatment agent. In this case, the other inorganic filler may be preferably an inorganic filler that is less likely to escape from the cured layer due to treatment with an alkaline solution and may be particularly preferably an inorganic filler having substantially no hydroxy groups on the surfaces. Alternatively, the other inorganic filler may be an inorganic filler that may possibly escape from the cured layer due to treatment with an alkaline solution, but provided that such escape scarcely contributes to the expansion of the cured layer.

The adhesive composition may further contain a plasticizer, a stabilizer, a tackifier, a colorant, a coupling agent, an antistatic, an antioxidant, etc.
(6) Thickness of Adhesive Layer

The thickness of the adhesive layer 11 can be set in consideration of the application of sealing, the thickness of the cured adhesive layer 11 after sealing, and the like. For example, the thickness may be preferably 2 μm or more, particularly preferably 5 μm or more, and further preferably 10 μm or more. From another aspect, the thickness may be preferably 500 μm or less, particularly preferably 300 μm or less, and further preferably 100 μm or less. When the thickness of the adhesive layer 11 is 2 μm or more, the adhesive layer 11 can be effectively embedded around the semiconductor chips. When the thickness of the adhesive layer 11 is 500 μm or less, the effect of protecting the chips after sealing can be well obtained.

### 2. Release Sheet

The sealing sheet 1 according to the present embodiment may be provided with a release sheet 12. The configuration of the release sheet 12 may be freely designed. For example, the release sheet 12 may include any of plastic films, such as polyethylene terephthalate, polybutylene terephthalate, polyethylene naphthalate and other polyester films, and polypropylene, polyethylene and other polyolefin films. It may be preferred to perform release treatment for the release surface (surface to be in contact with the adhesive layer 11 of the sealing sheet 1) of the release sheet 12. Examples of a release agent to be used for the release treatment include silicone-based, fluorine-based, and long-chain alkyl-based release agents.

The thickness of the release sheet 12 is not particularly limited, but may be usually about 20 μm or more and 250 μm or less.
3. Method for Producing Sealing Sheet

The sealing sheet 1 according to the present embodiment can be produced in a similar manner to that for the conventional sealing sheet. For example, the sealing sheet 1 can be produced through preparing a coating liquid that contains the adhesive composition and may further contain a solvent or a dispersion medium as necessary, coating the release surface of the release sheet 12 with the coating liquid using a die coater, a curtain coater, a spray coater, a slit coater, a knife coater, or the like to form a coating film, and drying the coating film. Properties of the coating liquid are not particularly limited, provided that the coating liquid can be used for coating. The coating liquid may contain a component for forming the adhesive layer 11 as a solute or a dispersant. The release sheet 12 may be removed as a process material or may also be used to protect the adhesive layer 11 until it is used for sealing.

A laminate in which release sheets 12 are laminated on both surfaces of the sealing sheet 1 can be produced by a method that includes coating the release surface of the previously described release sheet 12 with the coating liquid to form a coating film, drying the coating liquid to form a laminate composed of the adhesive layer 11 and the release sheet 12, and attaching the surface of the adhesive layer 11 of this laminate opposite to the release sheet 12 to the release surface of another release sheet 12 to obtain a laminate composed of the release sheet 12/adhesive layer 11/release sheet 12. At least one of the release sheets 12 of the laminate may be removed as a process material or may also be used to protect the adhesive layer 11 until it is used for sealing. Examples of the above solvent include organic solvents such as toluene, ethyl acetate and methyl ethyl ketone.

### <Method for Producing Semiconductor Device>

The sealing sheet 1 according to the present embodiment can be used to produce a semiconductor device. In particular, this production method includes a step of sealing one or more semiconductor chips using the sealing sheet 1 and a step of treating a sealed body obtained by the sealing with an alkaline solution. Examples of such a method for producing a semiconductor device include a method for producing a chip-embedded substrate, which method includes a step of sealing one or more semiconductor chips embedded in a substrate, a method that includes a step of sealing one or more semiconductor chips on a pressure sensitive adhesive sheet, and a method that includes a step of forming irregularities on the surface of a sealed body. Specific examples of the method include methods for producing semiconductor devices according to a first embodiment, a second embodiment, and a third embodiment, which will be described below.

1. Method for Producing Semiconductor Device according to First Embodiment

The method for producing a semiconductor device according to the first embodiment includes a step of providing one or more semiconductor chips on at least one surface of a base material (this step may be referred to as a “preparation step” in the production method according to the first embodiment, hereinafter), a step of laminating the adhesive layer 11 of the sealing sheet 1 according to the present embodiment so as to cover at least the semiconductor chips (this step may be referred to as a “lamination step” in this method, hereinafter), a step of curing the adhesive layer 11 to obtain a sealed body comprising: a cured layer formed by curing the adhesive layer 11; the semiconductor chips sealed with the cured layer; and the base material (this step may be referred to as a “curing step” in this method, hereinafter), a step of forming one or more holes penetrating from a surface of the cured layer opposite to the base material to an interface between the cured layer and the semiconductor chips (this step may be referred to as a “hole formation step” in this method, hereinafter), a step of exposing the sealed body formed with the holes to an alkaline solution to perform desmear treatment for the holes (this step may be referred to as an “alkaline treatment step” in this method, hereinafter), and a step of forming one or more electrodes connected electrically to the semiconductor chips via the holes to obtain a chip-embedded substrate (this step may be referred to as an “electrode formation step” in this method, hereinafter).

FIGS. 2 and 3 illustrate cross-sectional views for describing an example of the method for producing a semiconductor device according to the first embodiment. First, as illustrated in FIG. 2(a), the preparation step may be performed to provide semiconductor chips 2 on both surfaces of a base material 3. In this embodiment, semiconductor chips 2 disposed on one surface of the base material 3 and semiconductor chips 2 disposed on the other surface of the base material 3 may be provided at respective positions that do not overlap one another when viewed in the planar view of the base material 3. The method of providing the semiconductor chips 2 on the base material 3 is not particularly limited, and a commonly-used method can be employed. For example, the semiconductor chips 2 may be placed at predetermined positions of the base material 3 using a pickup device. The semiconductor chips 2 may be fixed on the base material 3 using a pressure sensitive adhesive, an adhesive, or the like. A commonly-used base material in the production of a chip-embedded substrate can be used as the material of the base material 3.

Subsequently, as illustrated in FIG. 2(b), the lamination step may be performed to laminate the adhesive layers 11 of the sealing sheets 1 according to the present embodiment on both surface sides of the base material 3. This lamination allows the semiconductor chips 2 provided on the base material 3 to be covered with the adhesive layers 11. When the adhesive layers 11 are laminated, the release sheets 12 may be removed from the adhesive layers 11 after the surfaces of the sealing sheets 1 opposite to the release sheets 12 are laminated on the base material 3. When the adhesive layers 11 are laminated, it may be preferred to laminate the adhesive layers 11 so that no spaces are formed around the semiconductor chips 2.

Then, as illustrated in FIG. 2(c), the curing step may be performed to cure the adhesive layers 11 to form cured layers 11′. It may be preferred to perform the curing by heating the adhesive layers 11. Thorough this curing, a sealed body 4 can be obtained, comprising the cured layers 11′, the semiconductor chips 2 sealed with the cured layers 11′, and the base material 3.

Then, as illustrated in FIG. 3(a), the hole formation step may be performed to form holes 5 penetrating the cured layers 11′. Specifically, the holes 5 may be formed to penetrate from the surfaces of the cured layers 11′ opposite to the base material 3 to interfaces between the cured layers 11′ and the semiconductor chips 2. The cross-sectional view of FIG. 3(a) illustrates an appearance in which two holes 5 are formed for one semiconductor chip 2. Formation of the holes 5 can be performed using a commonly-used method. For example, the holes 5 can be formed by irradiating the surfaces of the cured layers 11′ opposite to the base material 3 with laser. Such laser irradiation can be performed under a general irradiation condition using a laser irradiation device which is commonly used when forming holes.

Then, the alkaline treatment step may be performed to expose the sealed body 4 formed with the holes 5 to an alkaline solution. In the above hole formation step, when the holes 5 are formed in the cured layers 11′, residues (smear) of the components which constitute the cured layers 11′ may be generated, and the smear may remain in the holes 5. Such smear can be removed by exposing the sealed body 4 to an alkaline solution. Such treatment may also be called desmear treatment. By removing the smear from the holes 5, when electrodes are formed in the holes 5 in the electrode formation step, which will be described later, conduction failure of the electrodes can be suppressed. The treatment of exposing the sealed body 4 to an alkaline solution can be performed by a commonly-used method. For example, this treatment can be performed by immersing the sealed body 4 in an alkaline solution of 30° C. or higher and 120° C. or lower for 15 minutes.

A commonly-used solution for desmear treatment (desmear liquid) can be used as the above alkaline solution. For example, a sodium hydroxide solution that contains potassium permanganate, an aqueous solution that contains sodium permanganate and sodium hydroxide, or the like can be used. In addition to the aqueous solution that contains sodium permanganate and sodium hydroxide, an aqueous solution that contains potassium hydroxide can also be used as the above alkaline solution.

Finally, as illustrated in FIG. 3(b), the electrode formation step may be performed to form electrodes 6 in the holes 5. The electrodes 6 are electrically connected to the semiconductor chips 2 via the holes 5. Formation of the electrodes 6 can be performed by a commonly-used method. For example, a plating process using a metal such as copper may be performed for the surfaces of the cured layers 11′ formed with the holes 5 to embed the metal in the holes 5. Subsequently, unnecessary portions of the plated metal can be removed by etching or the like to form the electrodes 6 as remaining metal pieces. Through the formation of the electrodes 6, a chip-embedded substrate 7 can be obtained.

The cured layers 11′ formed using the sealing sheets 1 according to the present embodiment contain the inorganic filler which is surface-treated with the previously described surface treatment agent. In the inorganic filler, a large part of the hydroxy groups existing on the surfaces has disappeared due to the reaction with the surface treatment agent. Such an inorganic filler has a low affinity to an alkaline solution and, therefore, when the cured layers 11′ are exposed to the alkaline solution in the alkaline treatment step, the inorganic filler is less likely to escape from the cured layers 11′. As a result, even when the temperature of the cured layers 11′ rises during the subsequent steps for producing the semiconductor device and/or during the use of the produced semiconductor device, the expansion of the cured layers 11′ can be suppressed. Thus, the sealing sheet or sheets 1 according to the present embodiment can be used to produce a semiconductor device having a good performance.

In the chip-embedded substrate 7 obtained by the method for producing a semiconductor device according to the first embodiment, as the given semiconductor chips 2 are embedded therein, the number of semiconductor chips mounted on the surface or surfaces of the substrate can be reduced, so that the surface area of the substrate can be reduced. That is, the size of the substrate can be reduced. Moreover, as compared with the case in which all the electronic components such as conductor chips and semiconductor devices are mounted on the surface or surfaces of the substrate, lengths of the wirings between the embedded semiconductor chips and the electronic components mounted on the surface or surfaces can be shortened. This can improve the electrical characteristics and the density of electronic components disposed on or in the substrate after implementation.

2. Method for Producing Semiconductor Device according to Second Embodiment

The method for producing a semiconductor device according to the second embodiment includes a step of providing one or more semiconductor chips on the pressure sensitive adhesive surface of a pressure sensitive adhesive sheet (this step may be referred to as a “preparation step” in the production method according to the second embodiment, hereinafter), a step of laminating the adhesive layer 11 of the sealing sheet 1 according to the present embodiment so as to cover at least the semiconductor chips (this step may be referred to as an “adhesive layer lamination step” in this method, hereinafter), a step of curing the adhesive layer 11 to obtain a sealed body comprising: a cured layer formed by curing the adhesive layer 11; and the semiconductor chips sealed with the cured layer (this step may be referred to as a “curing step” in this method, hereinafter), a step of removing the pressure sensitive adhesive sheet from the sealed body (this step may be referred to as a “removal step” in this method, hereinafter), a step of laminating an interlayer insulating film on a surface of the sealed body exposed by removal of the pressure sensitive adhesive sheet (this step may be referred to as an “interlayer insulating film lamination step” in this method, hereinafter), a step of forming one or more holes penetrating from a surface of the interlayer insulating film opposite to the sealed body to an interface between the interlayer insulating film and the semiconductor chips (this step may be referred to as a “hole formation step” in this method, hereinafter), a step of exposing the sealed body laminated with the interlayer insulating film formed with the holes to an alkaline solution to perform desmear treatment for the holes (this step may be referred to as an “alkaline treatment step” in this method, hereinafter), and a step of forming one or more electrodes connected electrically to the semiconductor chips via the holes (this step may be referred to as an “electrode formation step” in this method, hereinafter).

FIGS. 4 and 5 illustrate cross-sectional views for describing an example of the method for producing a semiconductor device according to the second embodiment. First, as illustrated in FIG. 4(a), the preparation step may be performed to provide semiconductor chips 2 on one surface of a pressure sensitive adhesive sheet 8. The method of providing the semiconductor chips 2 on the pressure sensitive adhesive sheet 8 is not particularly limited, and a commonly-used method can be employed. For example, the semiconductor chips 2 may be placed at predetermined positions of the pressure sensitive adhesive sheet 8 using a pickup device. In this case, it may be preferred to provide the semiconductor chips 2 on a surface having the pressure sensitive adhesive properties of the pressure sensitive adhesive sheet 8. The pressure sensitive adhesive sheet 8 is not particularly limited, provided that the semiconductor chips 2 can be fixed on the sheet by the adhesive strength exerted by the sheet. The pressure sensitive adhesive sheet 8 may be composed of a base material and a pressure sensitive adhesive layer laminated on the base material or may also be a base material that has self-pressure sensitive adhesive properties. Such a base material and a pressure sensitive adhesive layer may preferably have heat resistance that can withstand the heating in the curing step, which will be described later. The pressure sensitive adhesive layer may preferably be energy ray curable. This allows the pressure sensitive adhesive layer to be cured by irradiation with energy rays, thus reducing the adhesive strength of the pressure sensitive adhesive sheet 8. As a result, the pressure sensitive adhesive sheet 8 can readily be removed from the sealed body 4 in the removal step, which will be described later.

Subsequently, as illustrated in FIG. 4(b), the adhesive layer lamination step may be performed to laminate the adhesive layer 11 of the sealing sheet 1 according to the present embodiment on the surface side of the pressure sensitive adhesive sheet 8 provided with the semiconductor chips 2. This lamination allows the semiconductor chips 2 provided on the pressure sensitive adhesive sheet 8 to be covered with the adhesive layer 11. When the adhesive layer 11 is laminated, the release sheet 12 may be removed from the adhesive layer 11 after the surface of the sealing sheet 1 opposite to the release sheet 12 is laminated on the pressure sensitive adhesive sheet 8. When the adhesive layer 11 is laminated, it may be preferred to laminate the adhesive layer 11 so that no spaces are formed around the semiconductor chips 2.

Then, as illustrated in FIG. 4(c), the curing step may be performed to cure the adhesive layer 11 to form a cured layer 11′. It may be preferred to perform the curing by heating the adhesive layer 11. Thorough this curing, a sealed body 4 can be obtained, comprising the cured layer 11′ and the semiconductor chips 2 sealed with the cured layer 11′.

Then, as illustrated in FIG. 4(d), the removal step may be performed to remove the pressure sensitive adhesive sheet 8 from the sealed body 4. As previously described, when the pressure sensitive adhesive sheet 8 includes a pressure sensitive adhesive layer having energy ray curability, the pressure sensitive adhesive layer may be irradiated with energy rays thereby to be cured before removal. This can reduce the adhesive strength of the pressure sensitive adhesive sheet 8 and the removal can readily be performed.

Then, as illustrated in FIG. 5(a), the interlayer insulating film lamination step may be performed to laminate an interlayer insulating film 9 on the surface of the sealed body 4 exposed due to the removal of the pressure sensitive adhesive sheet 8. The interlayer insulating film 9 can be laminated by a commonly-used method. For example, the interlayer insulating film 9 can be formed by film formation of a silicon-based material, an organic polymer, a silicon oxide film, or the like on the sealed body 4 using a CVD method, a spin-coating method, a dip-coating method, a spraying method, or other similar method.

Then, as illustrated in FIG. 5(b), the hole formation step may be performed to form holes 5 penetrating the interlayer insulating film 9. Specifically, the holes 5 may be formed to penetrate from the surface of the interlayer insulating film 9 opposite to the sealed body 4 to interfaces between the interlayer insulating film 9 and the semiconductor chips 2. The cross-sectional view of FIG. 5(b) illustrates an appearance in which two holes 5 are formed for one semiconductor chip 2. Formation of the holes 5 may be performed using a commonly-used method. For example, the holes 5 may be formed by irradiating the surface of the interlayer insulating film 9 opposite to the sealed body 4 with laser. Such laser irradiation can be performed under a general irradiation condition using a laser irradiation device which is commonly used when forming holes.

Then, the alkaline treatment step may be performed to expose the sealed body 4, which is laminated with the interlayer insulating film 9 formed with the holes 5, to an alkaline solution. In the above hole formation step, when the holes 5 are formed in the interlayer insulating film 9, residues (smear) of the components which constitute the interlayer insulating film 9 may be generated, and the smear may remain in the holes 5. The alkaline treatment step can be performed to remove the smear from the holes 5 and, when electrodes are formed in the holes 5 in the electrode formation step, which will be described later, conduction failure of the electrodes can be suppressed. The method of exposure to an alkaline solution and the type of the alkaline solution as used herein may be the same as those described in the method for producing a semiconductor device according to the first embodiment.

Finally, as illustrated in FIG. 5(c), the electrode formation step may be performed to form electrodes 6 in the holes 5. The electrodes 6 are electrically connected to the semiconductor chips 2 via the holes 5. Formation of the electrodes 6 can be performed by a commonly-used method. For example, the method of forming the electrodes 6 as described in the method for producing a semiconductor device according to the first embodiment can be used herein.

The cured layer 11′ formed using the sealing sheet 1 according to the present embodiment contains the inorganic filler which is surface-treated with the previously described surface treatment agent. In the inorganic filler, a large part of the hydroxy groups existing on the surfaces has disappeared due to the reaction with the surface treatment agent. Such an inorganic filler has a low affinity to an alkaline solution and, therefore, when the cured layer 11′ is exposed to the alkaline solution in the alkaline treatment step, the inorganic filler is less likely to escape from the cured layer 11′. As a result, even when the temperature of the cured layer 11′ rises during the subsequent steps for producing the semiconductor device and/or during the use of the produced semiconductor device, the expansion of the cured layer 11′ can be suppressed. Thus, the sealing sheet 1 according to the present embodiment can be used to produce a semiconductor device having a good performance.

The method for producing a semiconductor device according to the second embodiment allows for production of semiconductor packages such as fan-out wafer level packages, etc.

3. Method for Producing Semiconductor Device according to Third Embodiment

The method for producing a semiconductor device according to the third embodiment includes a step of providing one or more semiconductor chips on at least one surface of a base material or on the pressure sensitive adhesive surface of a pressure sensitive adhesive sheet (this step may be referred to as a “preparation step” in the production method according to the third embodiment, hereinafter), a step of laminating the adhesive layer 11 of the sealing sheet 1 according to the present embodiment so as to cover at least the semiconductor chips (this step may be referred to as a “lamination step” in this method, hereinafter), a step of curing the adhesive layer 11 to obtain a sealed body comprising: a cured layer formed by curing the adhesive layer 11; and the semiconductor chips sealed with the cured layer (this step may be referred to as a “curing step” in this method, hereinafter), and a step of exposing the sealed body to an alkaline solution to form irregularities on a surface of the sealed body (this step may be referred to as an “alkaline treatment step” in this method, hereinafter).

The preparation step, lamination step, and curing step in the method for producing a semiconductor device according to the third embodiment can be performed in the same manner as in the corresponding steps as described in the method for producing a semiconductor device according to the first embodiment.

On the other hand, in the method for producing a semiconductor device according to the third embodiment, the alkaline treatment step includes exposing the above sealed body 4 to an alkaline solution to form irregularities on the surface of the sealed body 4. The condition for this treatment can be appropriately determined in accordance with the irregularities to be formed. For example, this treatment can be performed by immersing the above sealed body 4 in an alkaline solution of 60° C. or higher and 90° C. or lower for 5 minutes. The alkaline solution may also be appropriately selected in accordance with the irregularities to be formed. For example, the alkaline solutions listed in the description of the method for producing a semiconductor device according to the first embodiment can be used.

The cured layer 11′ formed using the sealing sheet 1 according to the present embodiment contains the inorganic filler which is surface-treated with the previously described surface treatment agent. In the inorganic filler, a large part of the hydroxy groups existing on the surfaces has disappeared due to the reaction with the surface treatment agent. Such an inorganic filler has a low affinity to an alkaline solution and, therefore, when the cured layer 11′ is exposed to the alkaline solution in the alkaline treatment step, the inorganic filler is less likely to escape from the cured layer 11′. As a result, even when the temperature of the cured layer 11′ rises during the subsequent steps for producing the semiconductor device and/or during the use of the produced semiconductor device, the expansion of the cured layer 11′ can be suppressed. Thus, also when the sealing sheet 1 according to the present embodiment is used in the method for producing a semiconductor device, which method includes a step for the formation of surface irregularities using an alkaline solution, a semiconductor device having a good performance can be produced.

It should be appreciated that the embodiments heretofore explained are described to facilitate understanding of the present invention and are not described to limit the present invention. It is therefore intended that the elements disclosed in the above embodiments include all design changes and equivalents to fall within the technical scope of the present invention.

### EXAMPLES

Hereinafter, the present invention will be described further specifically with reference to Examples, Testing Examples, etc., but the present invention is not limited to the following Testing Examples, etc.

### Examples 1 and 2 and Comparative Examples 1 and 2

Each set of constituent components listed in Table 1 was mixed and diluted with methyl ethyl ketone to obtain an adhesive composition coating liquid having a solid content concentration of 40 mass %. The release surface of a release film having a surface treated with silicone for release treatment (available from LINTEC Corporation, product name “SP-PET381031”) was coated with the coating liquid, and the obtained coating film was dried in an oven at 100° C. for 1 minute thereby to obtain a sealing sheet comprising an adhesive layer of a thickness of 25 μm and the release film.

The surface treatment of each type of the inorganic filler listed in Table 1 was performed through stirring methyl ethyl ketone and 100 mass parts of an untreated inorganic filler at 40° C. in an eggplant flask, then adding 1 mass part of a surface treatment agent, and further stirring them for 180 minutes.

### Testing Example 1

### Surface Observation

The sealing sheet produced in each of Examples and Comparative Examples was laminated on a copper-clad laminate and then heated at 100° C. for 60 minutes and further at 170° C. for 60 minutes thereby to cure the adhesive layer. The laminate of the copper-clad laminate and the sealing sheet including the adhesive layer after curing was immersed in a sodium hydroxide solution containing potassium permanganate as an alkaline solution at 80° C. for 15 minutes. The surface of the sample for measurement after the immersion was photographed using a scanning electron microscope (available from Hitachi, Ltd., product name “S-4700”) under a condition of an acceleration voltage of 10 kV, an inclination angle of 30 degrees, and a magnification of 10,000 times. The photographs thus obtained are shown in FIGS. 6 to 9. Here, FIG. 6 shows a photograph according to Example 1, FIG. 7 shows a photograph according to Example 2, FIG. 8 shows a photograph according to Comparative Example 1, and FIG. 9 shows a photograph according to Comparative Example 2.

It can be found from the photographs shown in FIGS. 6 and 7 that white particles exist uniformly on the surfaces of the cured layers of Examples 1 and 2. The white particles are those of the remaining inorganic filler. That is, it can be found that in the cured layers formed using the sealing sheets of Examples 1 and 2, the escape of the inorganic filler from the surfaces substantially does not occur even after the treatment with the alkaline solution.

On the other hand, from the photographs shown in FIGS. 8 and 9, appearances can be found in which a large number of black depressions exist on the surfaces of the cured layers of Comparative Examples 1 and 2. The black depressions are voids caused due to the escape of the inorganic filler. That is, it can be found that in the cured layers formed using the sealing sheets of Comparative Examples 1 and 2, a large number of particles of the inorganic filler have escaped due to the treatment with the alkaline solution.

Here, details of the constituent components listed in Table 1 are as follows.

### <Thermoplastic Resin>

Bis A-type phenoxy resin: bisphenol A-type phenoxy resin (available from Mitsubishi Chemical Corporation, product name “jER1256”)

### <Thermoset Resin>

Bis A-type epoxy resin: bisphenol A-type epoxy resin (available from Mitsubishi Chemical Corporation, product name “jER828”)

Biphenyl-type epoxy resin: biphenyl-type epoxy resin (available from Nippon Kayaku Co., Ltd., product name “NC-3000-L”)

Naphthalene-type epoxy resin: naphthalene-type epoxy resin (available from DIC Corporation, product name “HP-4700”)

Biphenyl-type phenol: biphenyl-type phenol (available from Meiwa Plastic Industries, Ltd., product name “MEHC-7851-SS”)

### <Curing Catalyst>

Imidazole-based curing catalyst: 2-ethyl-4-methylimidazole (available from SHIKOKU CHEMICALS CORPORATION, product name “2E4MZ”)

### <Inorganic Filler>

Silazane-treated silica filler: filler obtained by surface-treating a silica filler (available from Admatechs Company Limited, product name “SO-C2,” average particle diameter: 0.5 μm, maximum particle diameter: 2 μm, shape: spherical) with 1,1,1,3,3,3-hexamethyldisilazane (available from Shin-Etsu Chemical Co., Ltd., product name “SZ-31,” minimum coverage area: 967 m²/g)

Dimethyldimethoxysilane-treated silica filler: filler obtained by surface-treating a silica filler (available from Admatechs Company Limited, product name “SO-C2,” average particle diameter: 0.5 μm, maximum particle diameter: 2 μm, shape: spherical) with dimethyldimethoxysilane (available from Shin-Etsu Chemical Co., Ltd., product name “KBM-22,” minimum coverage area: 649 m²/g)

Epoxysilane-treated silica filler: filler obtained by surface-treating a silica filler (available from Admatechs Company Limited, product name “SO-C2,” average particle diameter: 0.5 μm, maximum particle diameter: 2 μm, shape: spherical) with 3-glycidoxypropyltrimethoxysilane (available from Shin-Etsu Chemical Co., Ltd., product name “KBM-403,” minimum coverage area: 330 m²/g)

Vinylsilane-treated silica filler: filler obtained by surface-treating a silica filler (available from Admatechs Company Limited, product name “SO-C2,” average particle diameter: 0.5 μm, maximum particle diameter: 2 μm, shape: spherical) with vinyltrimethoxysilane (available from Shin-Etsu Chemical Co., Ltd., product name “KBM-1003,” minimum coverage area: 515 m²/g)

TABLE 1

| | | Content in adhesive composition (mass %) | | | |
|---|---|---|---|---|---|
| | | | | Comparative | Comparative |
| Constituent component of adhesive composition | | Example 1 | Example 2 | Example 1 | Example 2 |
| Thermoplastic resin | BisA-type phenoxy resin | 5.0 | 5.0 | 5.0 | 5.0 |
| Thermoset resin | BisA-type epoxv resin | 6.7 | 6.7 | 6.7 | 6.7 |
| | Biphenyl-type epoxy resin | 6.7 | 6.7 | 6.7 | 6.7 |
| | Naphthalene-type epoxy resin | 4.7 | 4.7 | 4.7 | 4.7 |
| | Biphenyl-type phenol | 19.1 | 19.1 | 19.1 | 19.1 |
| Curing catalyst | Imidazole-based curing catalyst | 0.1 | 0.1 | 0.1 | 0.1 |
| Inorganic filler | Silazane-treated silica filler | 57.7 | — | — | — |
| | Dimethyldimethoxysilane-treated | — | 57.7 | — | — |
| | silica filler | | | | |
| | Epoxysilane-treated silica filler | — | — | 57.7 | — |
| | Vinylsilane-treated silica filler | — | — | — | 57.7 |

As described above, the sealing sheets obtained in Examples are less likely to cause the inorganic filler to escape from the cured layers even through the treatment with an alkaline solution.

### INDUSTRIAL APPLICABILITY

The sealing sheet according to the present invention is less likely to cause the inorganic filler to escape from the cured layer, so that the cured layer may not readily expand due to heating. Thus, the sealing sheet according to the present invention can be suitably utilized for production of semiconductor devices such as a chip-embedded substrate and a fan-out wafer level package.

### DESCRIPTION OF REFERENCE NUMERALS

1 . . . Sealing sheet
   11 . . . Adhesive layer
   11′ . . . Cured layer
   12 . . . Release sheet
2 . . . Semiconductor chip
3 . . . Base material
4 . . . Sealed body
5 . . . Hole
6 . . . Electrode
7 . . . Chip-embedded substrate
8 . . . Pressure sensitive adhesive sheet
9 . . . Interlayer insulating film

1. A sealing sheet used for sealing of a semiconductor chip embedded in a substrate or a semiconductor chip on a pressure sensitive adhesive sheet in a method for producing a semiconductor device, the method comprising a treatment step using an alkaline solution,
the sealing sheet comprising at least an adhesive layer having curability,
the adhesive layer being formed of an adhesive composition, the adhesive composition containing a thermoset resin, a thermoplastic resin, and an inorganic filler, the inorganic filler being surface-treated with a surface treatment agent having a minimum coverage area of 550 m²/g or more and 1,500 m²/g or less.

2. The sealing sheet as recited in claim 1, wherein the surface treatment agent is at least one selected from the group consisting of a silazane compound, an alkoxysilane, and a silane coupling agent.

3. The sealing sheet as recited in claim 2, wherein the silazane compound is a compound having a structure represented by Formula (1):
SiR₃—N(H)—SiR₃ (1)
where each R independently represents a substituted or unsubstituted alkyl group having a carbon number of 1 or more and 6 or less.

4. The sealing sheet as recited in claim 1, wherein the inorganic filler is a silica filler or an alumina filler.

5. The sealing sheet as recited in claim 1, wherein an average particle diameter of the inorganic filler is 0.01 μm or more and 3.0 μm or less.

6. The sealing sheet as recited in claim 1, wherein a maximum particle diameter of the inorganic filler is 0.05 μm or more and 5.0 μm or less.

7. The sealing sheet as recited in claim 1, wherein the inorganic filler is spherical.

8. The sealing sheet as recited in claim 1, wherein the adhesive composition further contains an imidazole-based curing catalyst.

9. A method for producing a semiconductor device, comprising:
a step of providing one or more semiconductor chips on at least one surface of a base material;
a step of laminating the adhesive layer of the sealing sheet as recited in claim 1 so as to cover at least the semiconductor chips;
a step of curing the adhesive layer to obtain a sealed body comprising: a cured layer formed by curing the adhesive layer; the semiconductor chips sealed with the cured layer; and the base material;
a step of forming one or more holes penetrating from a surface of the cured layer opposite to the base material to an interface between the cured layer and the semiconductor chips;
a step of exposing the sealed body formed with the holes to an alkaline solution to perform desmear treatment for the holes; and
a step of forming one or more electrodes connected electrically to the semiconductor chips via the holes to obtain a chip-embedded substrate.

10. A method for producing a semiconductor device, comprising:
a step of providing one or more semiconductor chips on a pressure sensitive adhesive surface of a pressure sensitive adhesive sheet;
a step of laminating the adhesive layer of the sealing sheet as recited in claim 1 so as to cover at least the semiconductor chips;
a step of curing the adhesive layer to obtain a sealed body comprising: a cured layer formed by curing the adhesive layer; and the semiconductor chips sealed with the cured layer;
a step of removing the pressure sensitive adhesive sheet from the sealed body;
a step of laminating an interlayer insulating film on a surface of the sealed body exposed by removal of the pressure sensitive adhesive sheet;
a step of forming one or more holes penetrating from a surface of the interlayer insulating film opposite to the sealed body to an interface between the interlayer insulating film and the semiconductor chips;
a step of exposing the sealed body laminated with the interlayer insulating film formed with the holes to an alkaline solution to perform desmear treatment for the holes; and
a step of forming one or more electrodes connected electrically to the semiconductor chips via the holes.

11. A method for producing a semiconductor device, comprising:
a step of providing one or more semiconductor chips on at least one surface of a base material or on a pressure sensitive adhesive surface of a pressure sensitive adhesive sheet;
a step of laminating the adhesive layer of the sealing sheet as recited in claim 1 so as to cover at least the semiconductor chips;
a step of curing the adhesive layer to obtain a sealed body comprising: a cured layer formed by curing the adhesive layer; and the semiconductor chips sealed with the cured layer; and
a step of exposing the sealed body to an alkaline solution to form irregularities on a surface of the sealed body.
